(19) United States
(12) Patent Application Publication
(10) Pub. No.: US 2025/0185509 A1
(43) Pub. Date: Jun. 5, 2025

(54) METHODS FOR HEAT TREATING THERMOCOUPLES USING OHMIC HEATING AND RELATED SYSTEMS

(71) Applicant: Battelle Energy Alliance, LLC, Idaho Falls, ID (US)

(72) Inventor: Richard S. Skifton, Idaho Falls, ID (US)

(73) Assignee: Battelle Energy Alliance, LLC, Idaho Falls, ID (US)

(21) Appl. No.: 18/525,563

(22) Filed: Nov. 30, 2023

(51) Int. Cl. H10N 10/01; H05B 3/00

(52) U.S. Cl. CPC H10N 10/01; H05B 3/0004

(57) ABSTRACT

A method for heat treating a thermocouple includes connecting leads from a power source to conducting wires of a thermocouple and generating a substantially constant current at a target amperage from the power source. The substantially constant current may be applied to the conducting wires via the leads to heat the conducting wires via ohmic heating to an anneal temperature. The current from the power source to the conducting wires is stopped after a heat treatment time.

### STATEMENT REGARDING FEDERALLY SPONSORED RESEARCH OR DEVELOPMENT

This invention was made with government support under Contract Number DE-AC07-05-ID14517 awarded by the United States Department of Energy. The government has certain rights in the invention.

### TECHNICAL FIELD

This disclosure relates generally to heat treatment of instrumentation. More specifically, this disclosure relates to heat treatment during manufacture and repair of thermocouples.

### BACKGROUND

Thermocouples are a type of temperature sensor that works on the principle of the Seebeck effect. Thermocouples are widely used in various industries such as metallurgy, aerospace, and power generation. A thermocouple includes thermoelements of two dissimilar metals that are joined together at one end. When a junction of the two metals is heated or cooled, a voltage is generated that is proportional to a temperature difference between the two metals. The voltage generated is measured and converted into a temperature reading.

Thermocouples may lose accuracy over time through what is referred to as thermocouple drift. Thermocouple drift is more common when a thermocouple operates at high temperatures over a long period of time. To reduce thermocouple drift, a thermocouple may undergo one or more heat treatment processes prior to use. Such heat treatment processes may be time consuming, particularly for relatively long thermocouples (such as thermocouples of a few feet or greater).

### BRIEF SUMMARY

According to some embodiments of the disclosure, a method for heat treating a thermocouple is provided. The method may include connecting leads from a power source to conducting wires of a thermocouple. A substantially constant current at a target amperage may be generated from the power source, and the substantially constant current may be applied to the conducting wires via the leads to heat the conducting wires via ohmic heating to an anneal temperature. The current from the power source to the conducting wires may be stopped after a heat treatment time.

According to some embodiments, a method for heat treating a thermocouple may comprise connecting leads from a power source to conducting wires of a thermocouple, generating a current from the power source, applying the current from the power source via the leads to the conducting wires to heat an entire length of the conducting wires via ohmic heating, and stopping the current from the power source to the conducting wires after a heat treatment time.

According to some embodiments, a system for heat treating a thermocouple may include a thermocouple support attached to a stand. The thermocouple support may be configured to hold a thermocouple in a vertical position. The system may further include a power source comprising leads. The leads may be configured to attach to conducting wires of the thermocouple. The power source may be configured to provide a current to the conducting wires of the thermocouple to heat the thermocouple via ohmic heating.

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIG. 1 shows a schematic view of a thermocouple heat treatment system according to embodiments of the disclosure; and

FIG. 2 shows a method of heat treating a thermocouple according to embodiments of the disclosure.

### DETAILED DESCRIPTION

The illustrations presented herein are not actual views of any heat treatment system or apparatus, or any component thereof, but are merely idealized representations, which are employed to describe embodiments of the disclosure.

As used herein, the singular forms following “a,” “an,” and “the” are intended to include the plural forms as well, unless the context clearly indicates otherwise.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any heat treatment system or apparatus when utilized in a conventional manner. Furthermore, these terms may refer to an orientation of elements of any heat treatment system or apparatus as illustrated in the drawings.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.).

Thermocouples may experience thermocouple drift over time, which may result in the thermocouples providing inaccurate temperature readings. The likelihood of thermocouple drift increases when a thermocouple is used at high temperatures for a prolonged period of time and/or when irradiated over a prolonged period of time. Accordingly, in high-temperature applications, thermocouples may need to be replaced or recalibrated relatively often due to thermocouple drift.

Conventionally, to stabilize thermocouples and prevent thermocouple drift, the thermocouples may be heat treated during manufacturing. Such heat treatment may comprise placing a thermocouple in a furnace and heating the thermocouple for a given length of time until desired material properties of the thermocouple are achieved. In some applications, the thermocouple may be relatively long, for example 20 feet long or greater, and may not fit in its entirety in a conventional furnace for heat treatment by a conventional process. In such a conventional process, the thermocouple may be heat treated in sections until the entire length of the thermocouple is heat treated. However, such heat treatment processing of a thermocouple of substantial length may be relatively time consuming. For example, the time to heat treat four feet of a relatively long thermocouple in a conventional furnace may be several days. Thus, it is desirable to provide a way to heat treat a thermocouple in a manner that reduces the time used to heat treat the thermocouple.

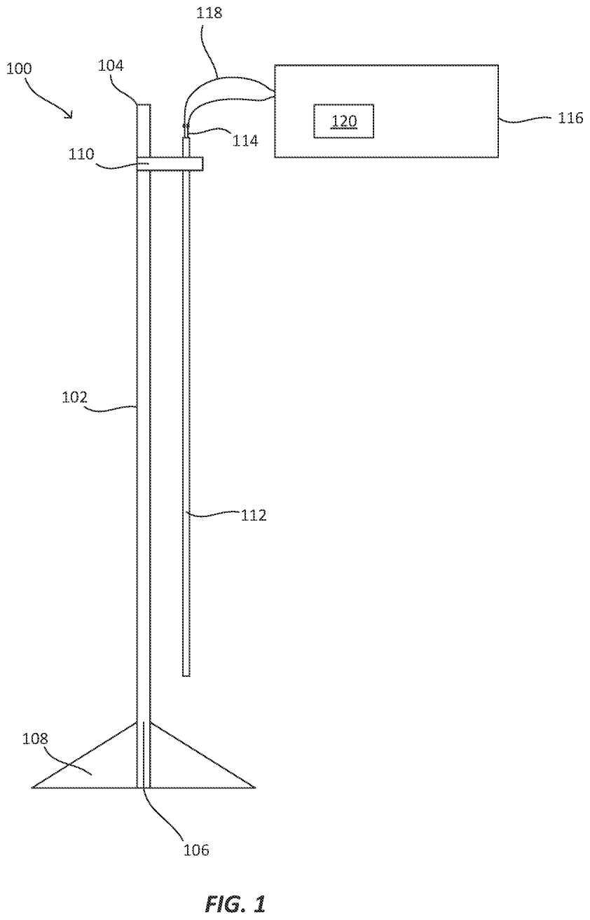

In some embodiments, ohmic heating may be applied to the thermocouple to heat treat the thermocouple, stabilizing the thermocouple to prevent thermocouple drift. Such ohmic heating may be applied to a new thermocouple during a manufacturing process or to an older (e.g., used) thermocouple needing repair. FIG. 1 shows a schematic view of a thermocouple heat treatment system according to embodiments of the disclosure. In FIG. 1, a thermocouple heat treatment system 100 (which also may be referred to as a thermocouple stabilization system) may comprise a stand 102 comprising a top end 104 and a bottom end 106. A base support 108 may be included at the bottom end 106 of the stand 102 to hold the stand 102 upright. The stand 102 may further comprise a thermocouple support 110, such as a clamp, that extends from the stand 102 and supports a thermocouple 112 to be heat treated. The thermocouple support 110 may be attached to the stand 102 near the top end 104 as shown in FIG. 1. The thermocouple 112 may, for example, be oriented vertically. In some embodiments, the thermocouple support 110 may be movable along the stand 102 to any desired height on the stand 102. The thermocouple support 110 may be configured to hold and support the thermocouple 112 near an end of the thermocouple 112 such that the thermocouple 112 is suspended from the thermocouple support 110.

The thermocouple 112 to be treated may be any type of thermocouple having a predetermined length and formed from predetermined materials, such as a Type-K thermocouple, a Type-N thermocouple, a Type-B thermocouple, or a HTIR thermocouple. The thermocouple 112 may comprise conducting wires 114 of different elements. The thermocouple 112 may further comprise a metal sheathing (not shown) surrounding the conducting wires 114. A mineral insulation (e.g., powder insulation) or other insulating material (e.g., silicon carbide) may also be contained within the metal sheathing of the thermocouple 112. The conducting wires 114 may be configured to extend (e.g., protrude) from an end of the thermocouple 112.

The thermocouple heat treatment system 100 may further comprise a power source 116 operably coupled to the thermocouple 112. The power source 116 may provide electrical power to facilitate the ohmic heating of the conducting wires 114 of the thermocouple 112. The power source 116 may connect (e.g., electrically connect) to the conducting wires 114 of the thermocouple 112 via leads 118. In some embodiments, a ground (not shown) may also be connected to the thermocouple 112. The power source 116 may further comprise a user interface 120. The user interface 120 may comprise one or more input devices to receive user input to control a power output of the power source 116. The user interface 120 may also comprise one or more output devices, such as a screen or other display showing an applied voltage and current output by the power source 116. The power source 116 may, for example, be a DC voltage source.

The power source 116 may be configured to provide an electrical current that is applied to the conducting wires 114 of the thermocouple 112. The electrical current may facilitate ohmic or resistive heating within the conducting wires 114 of the thermocouple to heat treat the thermocouple. In some embodiments, the power source 116 may be configured to provide a substantially constant current at a target amperage to the conducting wires 114 of the thermocouple 112. The power source 116 may provide a variable voltage over time to maintain the target amperage to the conducting wires 114. The target amperage and the associated voltage used during the method may vary depending on a given application, such as depending on the materials of the thermocouple 112, the length of the thermocouple 112, the metal sheathing and powder insulation used in the thermocouple 112, a diameter of the of the conducting wires 114, or the like. Other aspects such as phonon drag, magnetic flux, Seebeck coefficient or the like may be considered. For example, the target current may increase as the diameter of the conducting wires 114 increases. The target current may also increase as the length of the conducting wires 114 increases or as the electric resistivity in the conducting wires 114 increases. In some embodiments, the target amperage may range from about 0.5 amps to about 10 amps.

The current provided by the power source 116 to provide ohmic heating to the conducting wires 114 of the thermocouple 112 may be configured to heat the conducting wires 114 of the thermocouple 112 to a desired temperature that anneals the materials of the thermocouple 112. In some embodiments, the desired temperature (e.g., an anneal temperature) may be between about 40% and about 50% of a melting point of the materials of the conducting wires 114 of the thermocouple 112. For example, a Type-K thermocouple (having conducting wires of an aluminum alloy and chromium alloy, respectively) and a Type-N thermocouple (having conducting wires of different nickel-based alloys) may have a melting temperature of about 1300° C. The power source 116 may thus heat the thermocouple to an anneal temperature of between about 40% and about 50% of the melting temperature, or from about 520° C. to about 650° C. In another example, a high-temperature, irradiation resistant thermocouple (“HTIR thermocouple”) (having conducting wires formed from refractory metals such as molybdenum and niobium) may have a melting temperature between about 2400° C. and about 2600° C. The power source 116 may thus heat the HTIR thermocouple anywhere from about 960° C. to about 1300° C.

Without being bound by any theory, it is believed that the ohmic heating of the thermocouple 112 may facilitate rearrangement of short-range ordering of the alloys and atoms and eradicating dislocations or vacancy gradients within the materials used as the conducting wires 114 in the thermocouple 112. The ohmic heating may provide the thermocouple 112 with long-term accuracy and resiliency to thermocouple drift. Following the heat treatment, the thermocouple 112 may exhibit a more uniform (e.g., less damaged) crystal lattice. Therefore, the thermocouple 112 is more homogeneous than a thermocouple produced by a conventional process.

In some embodiments as shown in FIG. 1, the stand 102 and thermocouple support 110 may be configured to suspend the thermocouple 112 vertically. By way of example only, the thermocouple 112 may be oriented vertically so that the thermocouple 112 does not contact a portion of the thermocouple heat treatment system 100 except for at the thermocouple support 110. This may allow the thermocouple 112 to be separated (e.g., physically isolated) from potential conductive heat transfer points of contact aside from the thermocouple support 110. A height at which the thermocouple support 110 is positioned may be sufficient to maintain the thermocouple 112 above a surface on which the base support 108 is placed. This allows for a relatively uniform heating and cooling of the thermocouple 112 during and after the heat-treating process. In some embodiments, the thermocouple heat treatment system 100 may be placed in an inert gas environment or in a vacuum environment to prevent oxidation during the heat treatment. Other environments may also be possible, such as in water or in oil.

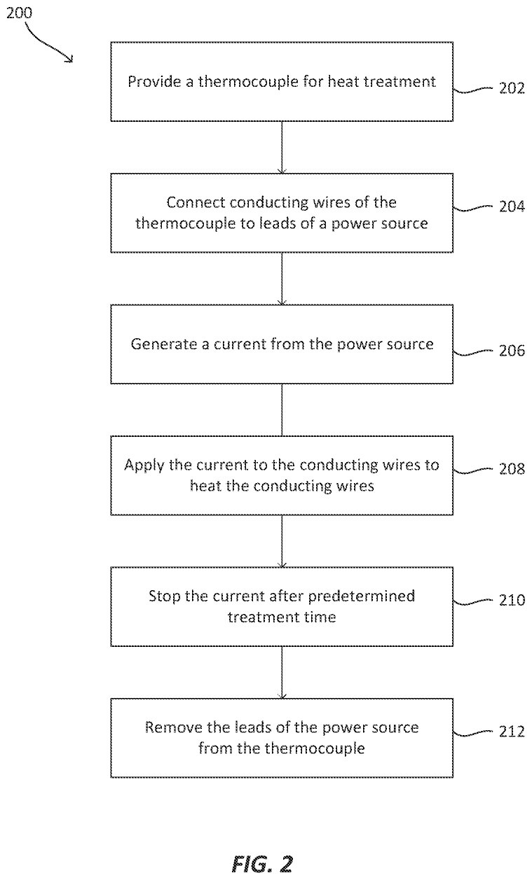

FIG. 2 shows a method of heat treating a thermocouple 200 according to embodiments of the disclosure. The method described in FIG. 2 may be a method that is conducted using the thermocouple heat treatment system 100 described with reference to FIG. 1. As shown in block 202 in FIG. 2, a thermocouple may be provided for heat treatment. Any desired thermocouple may be provided for heat treatment as described above. The thermocouple may be similar to the thermocouple 112 shown in FIG. 1. The thermocouple may be provided for heat treatment as part of a thermocouple manufacturing process. Alternatively, a used (e.g., damaged) thermocouple may be subjected to a similar process to repair or regenerate the thermocouple. The used thermocouple may be subjected to a process similar to that illustrated in FIG. 2 to reset the short-range ordering following use or damage of the thermocouple. In some embodiments, the thermocouple may be suspended from a thermocouple support attached to a stand, similar to the thermocouple support 110 and stand 102 shown in FIG. 1.

In block 204, leads of a power source may be connected to conductive wires of the thermocouple. For example, the leads 118 from the power source 116 may be connected to the conducting wires 114 of the thermocouple 112.

In block 206, a current may be generated from the power source to be provided to the thermocouple. For example, the power source 116 may be configured to generate a substantially constant current by generating a variable voltage to maintain the substantially constant current. In block 208, the current generated by the power source may be applied to the conducting wires of the thermocouple to heat the conductive wires. For example, the power source 116 may apply the substantially constant current at a target amperage to the conducting wires 114 of the thermocouple 112 via the leads 118. The voltage provided by the power source 116 may be variable to maintain the target amperage. The provided current may provide ohmic or resistive heating to the thermocouple. The current may be provided for a predetermined amount of time to obtain desired material properties. In some examples, the current may be provided to achieve a desired temperature at the thermocouple, such as an anneal temperature, for a predetermined time.

In some examples, the amount of time the current is applied to achieve desired material properties may be determined by the variable voltage of the power source. For example, when the current is first applied to the thermocouple, relatively low voltage is used to maintain the target amperage. As the thermocouple heats and short-range ordering occurs within the materials of the thermocouple, the voltage may be increased to maintain the target amperage. When the desired material properties of the thermocouple are achieved, the voltage to maintain the target amperage may reach an equilibrium and maintain a relatively constant voltage. The voltage may be monitored at the power source, such as power source 116 via the user interface 120.

In some examples, the surface temperature of the thermocouple may be measured during heat treating. The measurement of the surface temperature of the thermocouple may be used to estimate a temperature of the conducting wires in the thermocouple to determine the amount of time the current should be applied to the thermocouple.

In block 210, the current applied to the thermocouple may be discontinued after the predetermined treatment time. For example, the power source 116 may be controlled to stop providing current to the thermocouple 112 via the user interface 120.

In block 212, the leads of the power source may be removed from the thermocouple. The thermocouple may also be allowed to cool. The thermocouple may also be processed to remove oxidation from a surface of the thermocouple, such as via an abrasive pad.

The above-described system and method may provide several advantages. For example, the above-described system and method may be used to heat treat and stabilize a thermocouple in a matter of minutes, such as in about 30 minutes for a relatively long thermocouple, as compared to several days with conventional furnace heat treating methods. In some embodiments, the entire length of the thermocouple may be treated in less than 2 hours. In other embodiments, the entire length of the thermocouple may be treated in less than 1 hour. Furthermore, because the time used for heat treatment is drastically shortened, the risk of oxidation of the thermocouple is reduced, even when compared to conventional methods that are performed in an inert gas atmosphere. The heat treatment according to embodiments of the disclosure may be conducted at up to 300 times faster than conventional methods and may anneal an entire length of the thermocouple simultaneously. In conventional methods, due to the lengthy time required to heat treat a thermocouple, oxidation may occur due to trace amount of oxygen in the inert gas atmosphere. Due to the drastically reduced heat treatment time, the above-described system and method reduces oxidation during heat treatment, even when the system or method is not used in an inert gas or vacuum environment. Any oxidation occurring during the method may be easily removed, such as with an abrasive pad. Because the system may be used, and the method may be performed, in an open-air environment, the overall processing time may be further reduced because the thermocouple does not need to be transported between different environments.

As another advantage, the above-described system and method may heat treat the entire length of the thermocouple simultaneously as opposed to heat treating sections of the thermocouple. This results in more homogeneity in the materials in the thermocouple. Furthermore, conventional methods of heat treating a thermocouple do not heat treat an entire length of a relatively long thermocouple. For example, for a thermocouple on the order of feet or tens of feet, only a partial length of the thermocouple would be heat treated that is expected to be most exposed to high temperatures and/or irradiation while the remaining length of the thermocouple is left untreated. This is due to the amount of time required to heat treat the thermocouple in sections over a long length, such as a week or more. With the above-mentioned system and method, the entire length of the thermocouple is heat treated simultaneously within a manner of minutes, drastically decreasing the time for heat treating while also heat treating the entire length of the thermocouple.

The system and method may also allow for a thermocouple to be used for a longer amount of time before replacement. By regenerating a used thermocouple using the system and method according to embodiments of the disclosure, the thermocouple may exhibit a longer lifetime.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A method for heat treating a thermocouple, the method comprising:
connecting leads from a power source to conducting wires of a thermocouple;
generating a substantially constant current at a target amperage from the power source;
applying the substantially constant current via the leads to the conducting wires to heat the conducting wires via ohmic heating to an anneal temperature; and
stopping the substantially constant current from the power source to the conducting wires after a heat treatment time.

2. The method of claim 1, further comprising selecting the target amperage based on one or more of materials of the conducting wires of the thermocouple, a length of the thermocouple, a metal sheathing and powder insulation used in the thermocouple, and a diameter of the of the conducting wires of the thermocouple.

3. The method of claim 1, further comprising suspending the thermocouple from a thermocouple support attached to a stand.

4. The method of claim 1, further comprising removing oxidation from the thermocouple.

5. The method of claim 1, wherein applying the substantially constant current to the conducting wires comprises heating the conducting wires to between about 40% and about 50% of a melting point of materials of the conducting wires.

6. A method for heat treating a thermocouple, the method comprising:
connecting leads from a power source to conducting wires of a thermocouple;
generating a current from the power source;
applying the current from the power source via the leads to the conducting wires to heat an entire length of the conducting wires via ohmic heating; and
stopping the current from the power source to the conducting wires after a heat treatment time.

7. The method of claim 6, further comprising suspending the thermocouple from a thermocouple support attached to a stand.

8. The method of claim 6, further comprising applying an abrasive to remove oxidation from the thermocouple.

9. The method of claim 6, wherein applying the current from the power source to heat the conducting wires comprises heating the conducting wires to an anneal temperature.

10. The method of claim 9, wherein the anneal temperature is between about 40%-about 50% of a melting point of materials of the conducting wires.

11. The method of claim 6, wherein generating the current comprises generating a substantially constant current at a target amperage during the ohmic heating.

12. The method of claim 11, wherein generating the current comprises generating a variable voltage at the power source to maintain the target amperage during the ohmic heating.

13. The method of claim 12, further comprising determining the heat treatment time based on the variable voltage reaching an equilibrium to maintain a relatively constant voltage.

14. The method of claim 6, wherein the heat treatment time is less than one hour.

15. A method for repairing a thermocouple comprising the method of heat treating the thermocouple according to claim 6.

16. A system for heat treating a thermocouple, the system comprising:
a thermocouple support attached to a stand, the thermocouple support configured to hold a thermocouple in a vertical position; and
a power source comprising leads, the leads configured to attach to conducting wires of the thermocouple, the power source configured to provide a current to the conducting wires of the thermocouple to heat the thermocouple via ohmic heating.

17. The system of claim 16, wherein the system is disposed in an inert gas environment.

18. The system of claim 16, wherein the system prevents conductive heat transfer points of contact aside from the thermocouple support.

19. The system of claim 16, wherein the power source is configured to provide a substantially constant current at a target amperage.

20. The system of claim 19, wherein the power source is configured to provide a variable voltage to maintain the target amperage.
